(19) United States
(12) Patent Application Publication
(10) Pub. No.: US 2019/0096636 A1
(43) Pub. Date: Mar. 28, 2019

(54) PLASMA PROCESSING APPARATUS, PLASMA PROCESSING METHOD AND METHOD OF MANUFACTURING SEMICONDUCTOR DEVICE USING THE SAME

(71) Applicant: Samsung Electronics Co., Ltd., Suwon-si (KR)

(72) Inventors: Sang Ki NAM, Seongnam-si (KR); Sung Yong LIM, Seoul (KR); Beomjin YOO, Hwaseong-si (KR); Jongwoo SUN, Hwaseong-si (KR); Kyuhee HAN, Seongnam-si (KR); Kwangyoub HEO, Yongin-si (KR); Je-Woo HAN, Hwaseong-si (KR)

(21) Appl. No.: 15/940,621

(22) Filed: Mar. 29, 2018

(30) Foreign Application Priority Data
Sep. 27, 2017 (KR) 10-2017-0125462

(51) Int. Cl. H01J 37/32

(52) U.S. Cl. CPC H01J 37/32128; H01L 21/3065; H01J 2237/3347; H01J 37/3244

(57) ABSTRACT

A plasma processing apparatus includes a chamber including a space for processing a substrate, a substrate stage supporting the substrate within the chamber and including a lower electrode, an upper electrode within the chamber facing the lower electrode, a first power supply including a sinusoidal wave power source configured to apply a sinusoidal wave power to the lower electrode to form plasma within the chamber, and a second power supply configured to apply a nonsinusoidal wave power to the upper electrode to generate an electron beam.

### PRIORITY STATEMENT

This application claims priority under 35 U.S.C. § 119 to Korean Patent Application No. 10-2017-0125462, filed on Sep. 27, 2017 in the Korean Intellectual Property Office (KIPO), the contents of which are herein incorporated by reference in their entirety.

### BACKGROUND

### 1. Field

Example embodiments relate to a plasma processing apparatus, plasma processing method and a method of manufacturing a semiconductor device using the apparatus and/or the method. For example, example embodiments relate to a plasma processing apparatus configured to etch an object layer on a substrate using plasma and a plasma processing method using the same.

### 2. Description of the Related Art

Many types of semiconductor devices may be manufactured using plasma-based etching techniques. For example, a plasma etching apparatus such as a capacitively coupled plasma etching apparatus may generate plasma within a chamber to perform an etching process. However, when an etching process is performed to form a high aspect ratio hole, a wafer may be positively charged with positive ions, and thus, it may be difficult to etch in a vertical direction and to precisely control plasma density across the whole region of the wafer.

### SUMMARY

Example embodiments provide a plasma processing apparatus which may improve controllability of an etch profile.

Example embodiments provide a plasma processing method using the plasma processing apparatus.

Example embodiments provide a plasma processing apparatus configured to perform the plasma processing method.

According to example embodiments, a plasma processing apparatus includes a chamber including a space configured to process a substrate, a substrate stage configured to support the substrate within the chamber, the substrate stage including a lower electrode, an upper electrode disposed in the chamber, the upper electrode facing the lower electrode, a first power supply including a sinusoidal wave power source configured to apply a sinusoidal wave power to the lower electrode to form plasma within the chamber, and a second power supply configured to apply a nonsinusoidal wave power to the upper electrode to generate an electron beam.

According to example embodiments, a plasma processing apparatus includes a chamber including a space configured to process a substrate, a substrate stage configured to support the substrate within the chamber, the substrate stage including a lower electrode, a first upper electrode over the lower electrode, the upper electrode configured to face a first region of the substrate, a second upper electrode over the lower electrode, the second upper electrode configured to face a second region of the substrate, the second upper electrode being insulated from the first upper electrode, a first power supply including a sinusoidal wave power source configured to apply a sinusoidal wave power to the lower electrode to form plasma within the chamber, and a second power supply configured to apply a nonsinusoidal wave power to each of the first and second upper electrodes.

According to example embodiments, in a plasma processing method, a substrate is loaded on a substrate stage within a chamber, the substrate stage including a lower electrode. A sinusoidal wave power is applied to the lower electrode to form plasma within the chamber. A nonsinusoidal wave power is applied to an upper electrode to form an electron beam, the upper electrode facing the lower electrode. An object layer on the substrate is etched.

According to example embodiments, a plasma processing apparatus may include a substrate stage having a lower electrode to which a sinusoidal wave power is applied, and an upper electrode to which a nonsinusoidal wave power is applied, within a chamber. The upper electrode may include at least two first and second upper electrodes to which different nonsinusoidal wave powers are applied respectively.

As the nonsinusoidal wave power is applied to the upper electrode, an electron beam having constant energy may be generated regardless of an insulation material such as polymer deposited on the upper electrode during an etch process, and the electron beam may be irradiated onto a substrate to neutralize positive ions, thereby improving vertical etch performance for forming a high aspect ratio hole.

In example embodiments, the nonsinusoidal wave power applied to the upper electrode may generate the electron beam having desired energy, thereby controlling plasma density.

In certain embodiments, the nonsinusoidal wave powers may be applied to the first and second upper electrodes corresponding to respective regions of the substrate independently from each other to form electron beams having different energy, to thereby control plasma distribution.

### BRIEF DESCRIPTION OF THE DRAWINGS

Example embodiments will be more clearly understood from the following detailed description taken in conjunction with the accompanying drawings. FIGS. 1 to 13 represent non-limiting, example embodiments as described herein.

FIG. 1 is a block diagram illustrating a plasma processing apparatus in accordance with example embodiments.

FIG. 2 is a waveform diagram illustrating a sinusoidal wave power signal generated by a first power supply of the plasma processing apparatus in FIG. 1.

FIG. 3 is a waveform diagram illustrating a nonsinusoidal wave power signal generated by a second power supply of the plasma processing apparatus in FIG. 1.

FIG. 4 is a view illustrating plasma and electron beams generated within a chamber of the plasma processing apparatus in FIG. 1.

FIG. 5 is a block diagram illustrating the first power supply of the plasma processing apparatus in FIG. 1.

FIG. 6 is a waveform diagram illustrating a composite signal of a sinusoidal wave power and a nonsinusoidal wave power generated by the first power supply in FIG. 5.

FIG. 7 is a block diagram illustrating a plasma processing apparatus in accordance with example embodiments.

FIG. 8 is a plan view illustrating a first upper electrode and a second upper electrode of the plasma processing apparatus in FIG. 8.

FIG. 9 is a view illustrating plasma and electron beams generated within a chamber of the plasma processing apparatus in FIG. 7.

FIG. 10 is a block diagram illustrating a plasma processing apparatus in accordance with example embodiments.

FIG. 11 is a plan view illustrating a first upper electrode and a second upper electrode of the plasma processing apparatus in FIG. 10.

FIG. 12 is a flow chart illustrating a plasma processing method in accordance with example embodiments.

FIG. 13 is a cross-sectional view illustrating a method of forming a pattern of a semiconductor device in accordance with example embodiments.

### DETAILED DESCRIPTION

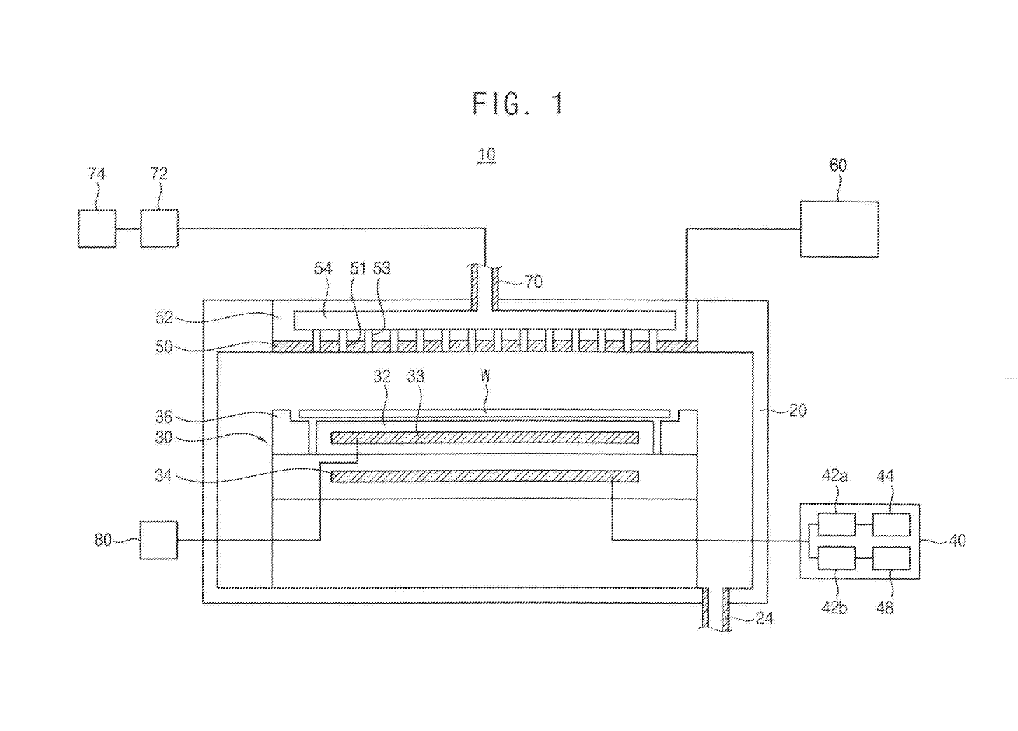

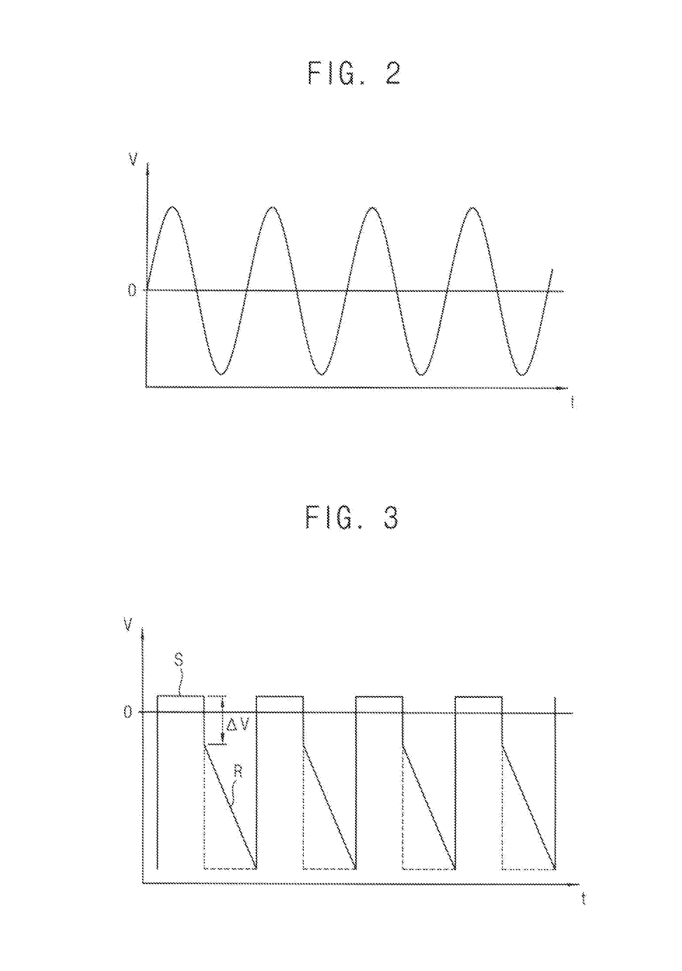

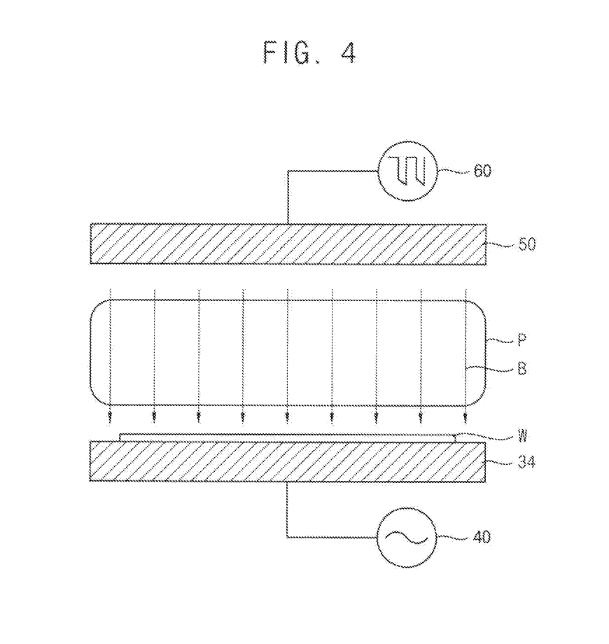

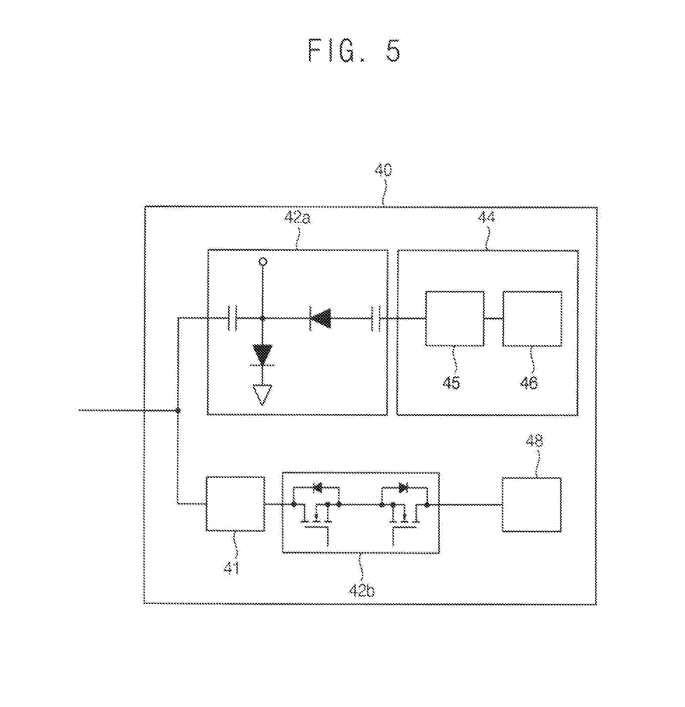

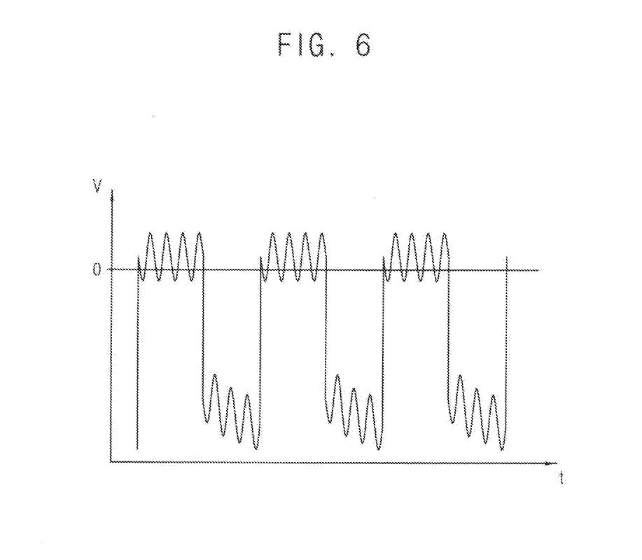

FIG. 1 is a block diagram illustrating a plasma processing apparatus in accordance with example embodiments. FIG. 2 is a waveform diagram illustrating a sinusoidal wave power signal generated by a first power supply of the plasma processing apparatus in FIG. 1. FIG. 3 is a waveform diagram illustrating a nonsinusoidal wave power signal generated by a second power supply of the plasma processing apparatus in FIG. 1. FIG. 4 is a view illustrating plasma and electron beams generated within a chamber of the plasma processing apparatus in FIG. 1. FIG. 5 is a block diagram illustrating the first power supply of the plasma processing apparatus in FIG. 1. FIG. 6 is a waveform diagram illustrating a composite signal of a sinusoidal wave power and a nonsinusoidal wave power generated by the first power supply in FIG. 5.

Referring to FIGS. 1 to 6, a plasma processing apparatus 10 may include a chamber 20, a substrate stage 30 having a lower electrode 34, an upper electrode 50, a first power supply 40 and a second power supply 60. The plasma processing apparatus 10 may further comprise a gas supply unit, an exhaust unit, etc.

In example embodiments, the plasma processing apparatus 10 may be an apparatus configured to etch a layer on a substrate such as a wafer W disposed within the capacitively coupled plasma (CCP) chamber. However, it is not limited thereto. Here, the substrate may include a semiconductor substrate, a glass substrate, etc.

The substrate stage 30 may be arranged within the chamber 20 to support the substrate. For example, the substrate stage 30 may serve as a susceptor for supporting the wafer W thereon. The substrate stage 30 may include a support plate 32 having an electrostatic electrode 33 for holding the wafer W using electrostatic force. The wafer W may be adsorptively held on the electrostatic electrode 33 when a direct current is applied thereto by a DC power source 80 through an ON-OFF switch (not illustrated).

The substrate stage 30 may include the circular plate-shaped lower electrode 34 under the support plate 32. The lower electrode 34 may be installed to be movable upwardly and downwardly by a driving portion (not illustrated). The substrate stage 30 may include a focus ring 36 which is arranged along a circumference of the support plate 32 to surround the wafer W. The focus ring 36 may have a ring shape.

Although it is not illustrated in the figures, a heater, a plurality of fluid lines, etc. may be installed in the substrate stage 30. The heater may be electrically connected to a power source to heat the wafer W through the support plate 32. The heater may include a coil (e.g., a heating coil as a heating element) having a spiral shape. The fluid line may be provided as a cooling channel through which a heat transfer gas circulates. The fluid line may be installed in the support plate 32 to have a spiral shape.

A gate (not illustrated) for loading/unloading of the wafer W may be provided in a sidewall of the chamber 20. The wafer W may be loaded/unloaded onto/from the substrate stage through the gate.

The exhaust unit may be connected to an exhaust port 24 which is installed in a bottom portion of the chamber 20, through an exhaust line. The exhaust unit may include a vacuum pump such as a turbo-molecular pump or the like, to control a pressure of the chamber 20 so that the processing space inside the chamber 20 may be depressurized to a desired vacuum level. For example, by-products derived from manufacturing processes and residual gases remaining after manufacturing processes may be discharged through the exhaust port 24.

The upper electrode 50 may be disposed over the substrate stage 30 such that the upper electrode 50 faces the lower electrode 34. The chamber space between the upper electrode 50 and the lower electrode 34 may be used as a plasma generation region. The upper electrode 50 may have a surface that faces the wafer W disposed on the substrate stage 30.

The upper electrode 50 may be disposed at an upper portion of the chamber 20 and supported by an insulation shield member (not illustrated). The upper electrode 50 may be provided as a part of a shower head for supplying a gas into the chamber 20. The upper electrode 50 may have an electrode plate having a circular shape. The upper electrode 50 may include a plurality of injection holes 51 which are formed to penetrate through the upper electrode 50 and are configured to supply the gas into the chamber 20.

For example, the shower head may include an electrode support plate 52 which supports the upper electrode 50 and diffuses the gas such that the gas is injected through the injection holes 51 of the upper electrode 50. The electrode support plate 52 may include a gas diffusion room 54 therein, and gas passages 53 may be formed in the electrode support plate 52 for the gas diffusion room 54 to be connected to the injection holes 51. The upper electrode 50 may be installed detachably to a lower surface of the electrode support plate 52. The electrode support plate 52 may include a conductive material such as aluminum, and may have a water cooling channel therein.

The gas supply unit may include a gas supply line 70, a flow controller 72 and a gas supply source 74, such as gas supply elements. The gas supply line may be connected to the gas diffusion room 54 of the electrode support plate 52, and the flow controller 72 may control an amount of the gas supplied into the chamber 20 through the gas supply line 70. For example, the gas supply source 74 may include a plurality of gas tanks, and the flow controller 72 may include a plurality of mass flow controllers (MFCs) corresponding to the gas tanks. The mass flow controllers may control independently the amounts of the supplied gases respectively.

In example embodiments, the first power supply 40 may apply a sinusoidal wave power to the lower electrode 34 to generate plasma within the chamber 20. The second power supply 60 may apply a nonsinusoidal wave power to the upper electrode 50 to generate an electron beam.

As illustrated in FIG. 2, the power signal applied to the lower electrode 34 may have a sinusoidal voltage waveform. For example, the sinusoidal wave power may be a RF (radio frequency) power having a frequency range of about 27 MHz to about 2.45 GHz and a RF power range of about 100 W to about 1000 W.

As illustrated in FIG. 3, the power signal applied to the upper electrode 50 may have a nonsinusoidal voltage waveform. The second bias power signal may have a DC pulse portion (S) and a ramp portion (R). The ramp portion (R) may be a portion which is modulated by a compensation current, and may have a waveform which declines gradually over time while decreasing from the maximum to the minimum of the DC pulse portion (S), e.g., a negative slope. For example, the nonsinusoidal voltage waveform may be similar to a square voltage waveform. For example, the nonsinusoidal voltage waveform may be similar to a delayed square voltage waveform as shown in FIG. 3. For example, the nonsinusoidal voltage waveform may be a periodic waveform having a DC pulse portion and a ramp portion.

As illustrated in FIG. 4, the sinusoidal wave power may be applied to the lower electrode 34 to generate plasma P within the chamber 20, and the nonsinusoidal wave power may be applied to the upper electrode 50 to generate an electron beam B having predetermined constant energy. The electron beam B generated from the upper electrode 50 may be accelerated across a sheath (e.g., an electrostatic sheath or a Debye sheath) and irradiated onto the wafer W disposed on the lower electrode 34.

As the nonsinusoidal wave power is applied to the upper electrode 50, the electron beam B having constant energy may be generated regardless of an insulation material such as polymer deposited on the upper electrode 50 during an etch process, and may be irradiated onto the wafer W to neutralize positive ions (e.g., attached or accumulated on the wafer W), thereby improving controllability of an etch profile for forming a high aspect ratio hole, e.g., a narrow and deep hole. For example, the electron beam B may have constant energy even though an insulation layer is deposited on the upper electrode 50 when the nonsinusoidal wave power is applied to the upper electrode 50. The nonsinusoidal wave power applied to the upper electrode 50 may be controlled to generate the electron beam B having desired energy, thereby increasing a density of plasma P. For example, the energy of the electron beam B may be adjusted by controlling the nonsinusoidal wave power applied to the upper electrode 50, and a desired density of plasma P may be obtained. The control of power supplied by the first power supply 40 and the second power supply 60 may be implemented with hardware and software configured to control the power (e.g., a computer system connected to each power supply may send a signal to the power supplies to control when the power is on and when the power is off, and to control the types of waves and amount of power output by the power supplies.

In example embodiments, the first power supply 40 may apply selectively or simultaneously a sinusoidal wave power and a nonsinusoidal wave power to the lower electrode 34.

As illustrated in FIG. 5, the first power supply 40 may include a sinusoidal wave power source 44 for applying the sinusoidal wave power to the lower electrode 34 and a nonsinusoidal wave power source 48 for applying the nonsinusoidal wave power to the lower electrode 34.

For example, the first power supply 40 may include a switching portion, such as a switching circuit, configured to apply selectively or simultaneously the sinusoidal wave power from the sinusoidal wave power source 44 and the nonsinusoidal wave power from the nonsinusoidal wave power source 48 to the lower electrode 34. The switching portion may include a first switching portion 42a (e.g., first portion of a switching circuit) disposed between the sinusoidal wave power source 44 and the lower electrode 34 to switch supply of the sinusoidal wave power and a second switching portion 42b (e.g., second portion of a switching circuit) disposed between the nonsinusoidal wave power source 48 and the lower electrode 34 to switch supply of the nonsinusoidal wave power.

For example, the, sinusoidal wave power source 44 may include a RF power source 46 for generating a radio frequency (RF) signal and an RF matcher 45 for matching impedance of the RF signal generated by the RF power source. The sinusoidal wave power source 44 may be electrically connected to the lower electrode 34 through a sinusoidal wave power line. The first switching portion 42a may be installed in the sinusoidal wave power line. The first switching portion 42a may include a PIN diode. For example, the PIN diode may include an undoped intrinsic semiconductor region between a p-type semiconductor and an n-type semiconductor.

The nonsinusoidal wave power source 48 may be electrically connected to the lower electrode 34 through a nonsinusoidal wave power line. The second switching portion 42b may be installed in the nonsinusoidal wave power line. The second switching portion 42b may include a bidirectional switch or a vacuum relay.

When the first switching portion 42a is turned ON and the second switching portion 42b is turned OFF, the sinusoidal wave power may be applied to the lower electrode 34. When the first switching portion 42a is turned OFF and the second switching portion 42b is turned ON, the nonsinusoidal wave power may be applied to the lower electrode 34. When the first and second switching portions 42a and 42b are turned ON, as illustrated in FIG. 6, a composite signal of the sinusoidal wave power and the nonsinusoidal wave power may be applied to the lower electrode 34.

Since the nonsinusoidal wave power is applied to the lower electrode 34, ion energy having a desired distribution may be generated in the surface of the wafer W. For example, the nonsinusoidal wave power applied to the lower electrode 34 may be controlled to adjust the ion energy generated in the surface of the wafer W.

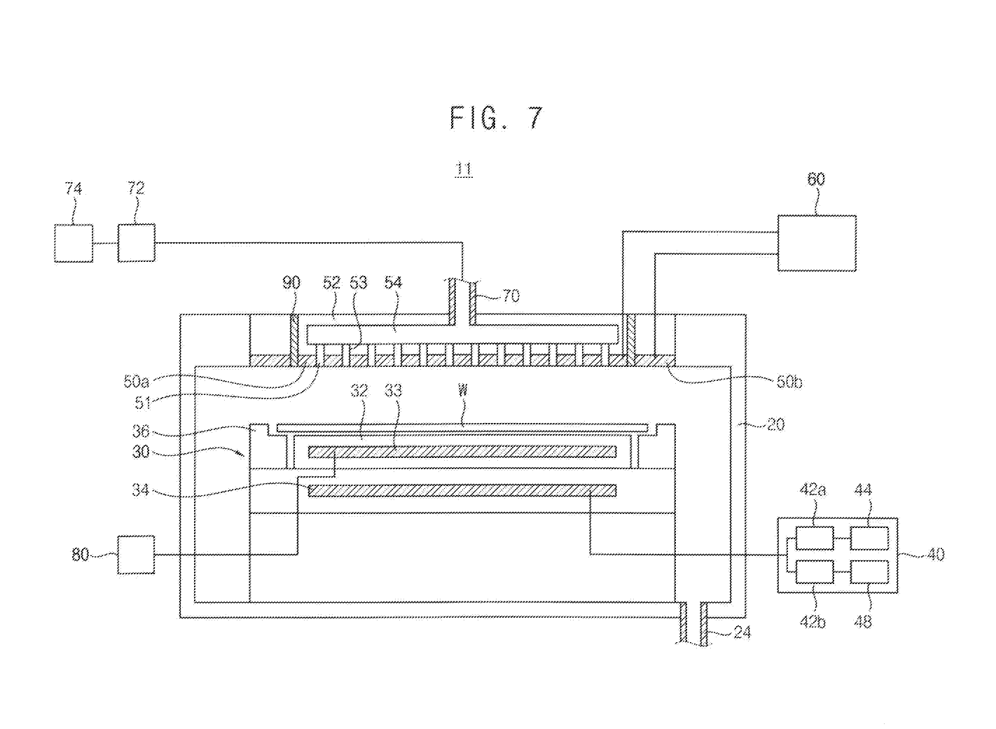

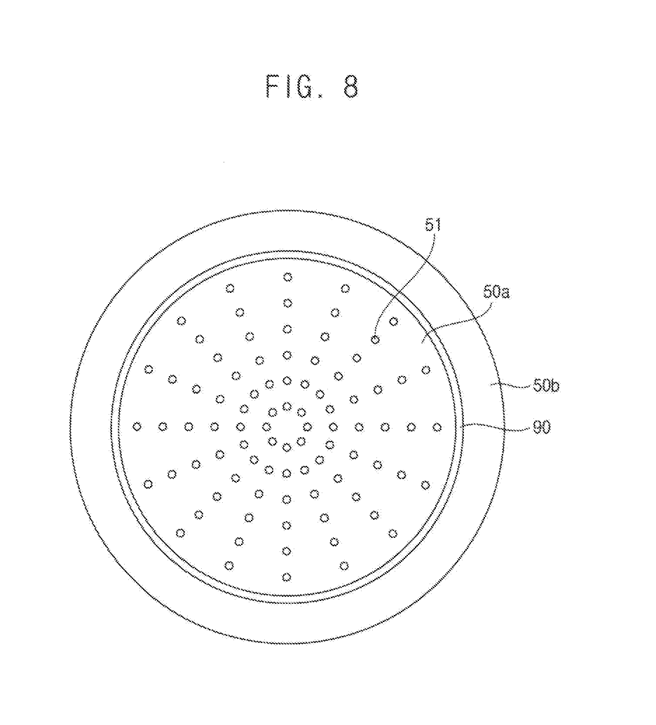

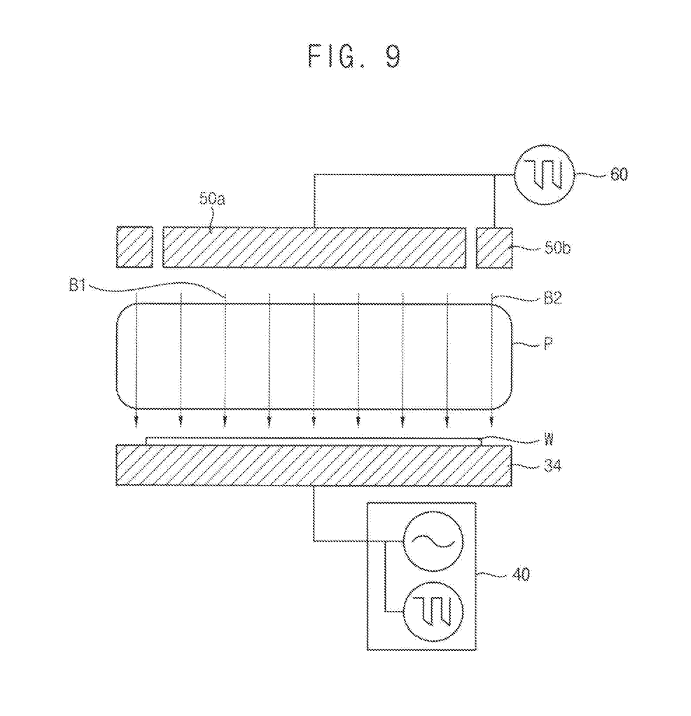

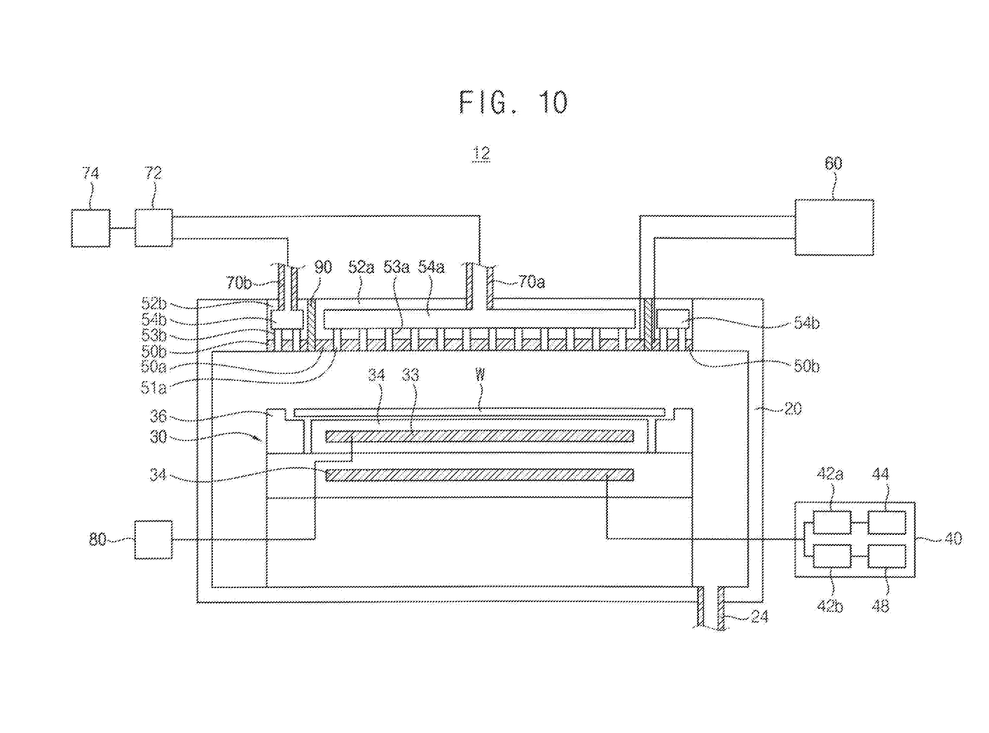

FIG. 7 is a block diagram illustrating a plasma processing apparatus in accordance with example embodiments. FIG. 8 is a plan view illustrating a first upper electrode and a second upper electrode of the plasma processing apparatus in FIG. 8. FIG. 9 is a view illustrating plasma and electron beams generated within a chamber of the plasma processing apparatus in FIG. 7. The plasma processing apparatus may be substantially the same as or similar to the plasma processing apparatus described with reference to FIGS. 1 to 6, except for first and second upper electrodes. Thus, same reference numerals will be used to refer to the same or like elements and repetitive explanation concerning the same elements may be omitted below.

Referring to FIGS. 7 to 9, an upper electrode of a plasma processing apparatus 11 may include a first upper electrode 50a arranged over a substrate stage 30 to face a first region of a wafer W and a second upper electrode 50b arranged over the substrate stage 30 to face a second region of the wafer W. For example, the first upper electrode 50a may face a first region of the substrate stage 30 and may be configured to face a first region of the wafer W disposed on the substrate stage 30. In addition, the second upper electrode 50b may face a second region of the substrate stage 30 and may be configured to face a second region of the wafer W disposed on the substrate stage 30. A second power supply 60 of the plasma processing apparatus 11 may apply a first nonsinusoidal wave power to the first upper electrode 50a and a second nonsinusoidal wave power having a predetermined ratio with respect to the first nonsinusoidal wave power to the second upper electrode 50b. For example, the second power supply 60 may be configured to change a ratio of the powers of the first and second nonsinusoidal wave powers respectively applied to the first and second upper electrodes 50a and 50b.

In example embodiments, the first upper electrode 50a may be provided as a part of a shower head for supplying a gas into a chamber 20. The shower head may include an electrode support plate 52 which supports the first upper electrode 50a.

As illustrated in FIG. 8, the first upper electrode 50a may include a first electrode plate having a circular shape corresponding to a middle region of the wafer W, and the second upper electrode 50b may include a second electrode plate having an annular shape corresponding to a peripheral region of the wafer W. The first upper electrode 50a and the second upper electrode 50b may be insulated from each other. For example, a dielectric ring member 90 may be disposed between the first upper electrode 50a and the second upper electrode 50b.

The first upper electrode 50a may include a plurality of injection holes 51 which are formed to penetrate through the first upper electrode 50a and are configured to supply the gas into the chamber 20. The electrode support plate 52 may include a gas diffusion room 54 therein, and gas passages 53 may be formed in the electrode support plate 52 for the gas diffusion room 54 to be connected to the injection holes 51. The first upper electrode 50a may be installed detachably to a lower surface of the electrode support plate 52. Accordingly, the shower head may inject the gas which is diffused through the gas diffusion room 54 into the chamber 20 through the injection holes 51 of the first upper electrode 50a.

In example embodiments, the first and second nonsinusoidal wave powers may be adjusted to have a predetermined ratio. For example, the second power supply 60 may include a first nonsinusoidal wave power source for applying the first nonsinusoidal wave power to the first upper electrode 50a and a second nonsinusoidal wave power source for applying the second nonsinusoidal wave power to the second upper electrode 50b. The first and second nonsinusoidal power sources may apply the nonsinusoidal wave powers to the first and second upper electrodes 50a and 50b independently from each other.

As illustrated in FIG. 9, the first nonsinusoidal wave power may be applied to the first upper electrode 50a to generate a first electron beam B1 having a first energy, and the second nonsinusoidal wave power may be applied to the second upper electrode 50b to generate a second electron beam B2 having a second energy. Energy of the first electron beam and energy of the second electron beam may be controlled independently from each other across the wafer W, to thereby adjust plasma distribution. For example, power of electron beams irradiating the wafer W may depend on a region of the wafer W. For example, as electron beams having different energy are irradiated onto the middle region and the peripheral region of the wafer W respectively, plasma density and sheath thickness of the middle region and the peripheral region of the wafer W may be controlled differently.

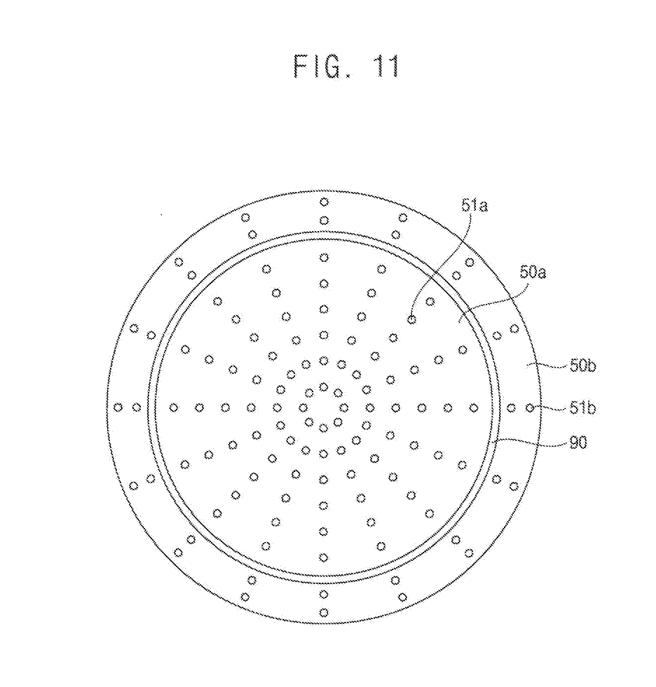

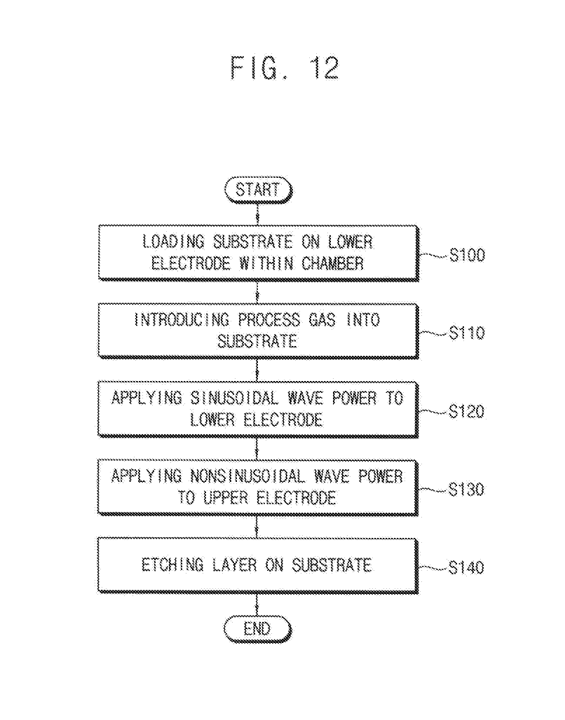

FIG. 10 is a block diagram illustrating a plasma processing apparatus in accordance with example embodiments. FIG. 11 is a plan view illustrating a first upper electrode and a second upper electrode of the plasma processing apparatus in FIG. 10. The plasma processing apparatus may be substantially the same as or similar to the plasma processing apparatus described with reference to FIGS. 7 to 9, except for a second upper electrode. Thus, same reference numerals will be used to refer to the same or like elements and repetitive explanation concerning the same elements may be omitted below.

Referring to FIGS. 10 and 11, an upper electrode of a plasma processing apparatus 12 may include a first upper electrode 50a arranged over a substrate stage 30 to face a first region of a wafer W and a second upper electrode 50b arranged over the substrate stage 30 to face a second region of the wafer W. For example, the first upper electrode 50a may face a first region of the substrate stage 30 and may be configured to face a first region of the wafer W disposed on the substrate stage 30. For example, the second upper electrode 50b may face a second region of the substrate stage 30 and may be configured to face a second region of the wafer W disposed on the substrate stage 30. A second power supply 60 of the plasma processing apparatus 12 may apply a first nonsinusoidal wave power to the first upper electrode 50a and a second nonsinusoidal wave power having a predetermined ratio with respect to the first nonsinusoidal wave power to the second upper electrode 50b.

In example embodiments, the first and second upper electrodes 50a and 50b may be provided as a part of a shower head for supplying a gas into a chamber 20. The shower head may include a first electrode support plate 52a which supports the first upper electrode 50a and a second electrode support plate 52b which supports the second upper electrode 50b.

As illustrated in FIG. 10, the first upper electrode 50a may include a first electrode plate having a circular shape corresponding to a middle region of the wafer W, and the second upper electrode 50b may include a second electrode plate having an annular shape corresponding to a peripheral region of the wafer W. The first upper electrode 50a and the second upper electrode 50b may be insulated from each other. For example, a dielectric ring member 90 may be disposed between the first upper electrode 50a and the second upper electrode 50b.

The first upper electrode 50a may include a plurality of first injection holes 51a which are formed to penetrate through the first upper electrode 50a and are configured to supply the gas into the chamber 20. The first electrode support plate 52a may include a first gas diffusion room 54a therein, and first gas passages 53a may be formed in the first electrode support plate 52a for the first gas diffusion room 54a to be connected to the first injection holes 51a. The first upper electrode 50a may be installed detachably to a lower surface of the first electrode support plate 52a.

The second upper electrode 50b may include a plurality of second injection holes 51b which are formed to penetrate through the second upper electrode 50b and are configured to supply the gas into the chamber 20. The second electrode support plate 52b may include a second gas diffusion room 54b therein, and second gas passages 53b may be formed in the second electrode support plate 52b for the second gas diffusion room 54b to be connected to the second injection holes 51b. The second upper electrode 50b may be installed detachably to a lower surface of the second electrode support plate 52b. The first gas passage 53a may have a cylindrical shape, and the second gas passage 53b may have an annular shape.

The first gas diffusion room 54a may be connected to a first gas supply line 70a, and the second gas diffusion room 54b may be connected to a second gas supply line 70b. A flow controller may control an amount of the gas introduced into the chamber through the first and second gas supply lines 70a and 70b. Thus, the amount of plasma generated on a middle region and a peripheral region of the chamber 20 may be adjusted selectively. For example, the plasma density of the center region and the plasma density of the peripheral region of the chamber 20 may be controlled by independently controlling the gas supply through the first and second gas supply lines 70a and 70b.

In this embodiment, the shower head may include two upper electrodes and two electrode support plates. In other embodiments, the shower head may include at least three upper electrodes and at least three electrode support plates.

Hereinafter, a method of processing a substrate using the plasma processing apparatus in FIG. 1 will be explained.

FIG. 12 is a flow chart illustrating a plasma processing method in accordance with example embodiments.

Referring to FIGS. 1 and 12, after a substrate is loaded into a chamber 20 (S100), a process gas may be supplied into the chamber (S110).

First, a semiconductor wafer W may be loaded on a support plate 32 of a substrate stage 30 within the chamber 20. The process gas (for example, an etching gas) may be introduced into the chamber 20 through a gas supply line 70 and then a pressure of the chamber 20 may be controlled to a desired vacuum level by a gas exhaust unit connected to an exhaust port 24.

Then, a sinusoidal wave power may be applied to a lower electrode 34 to generate plasma within the chamber 20 (S120), a nonsinusoidal wave power may be applied to an upper electrode 50 to generate an electron beam (S130), and then, an etch process may be performed on a layer formed on the wafer W (S140).

A first power supply 40 may apply the sinusoidal wave power to the lower electrode 34 to generate plasma within the chamber 20. The power signal applied to the lower electrode 34 may have a sinusoidal voltage waveform. For example, as the radio frequency power having a predetermined frequency (for example, 13.56 MHz) is applied to the upper electrode 50, an electromagnetic field induced by the lower electrode 34 may be applied to a source gas within the chamber 20 to generate plasma.

A second power supply 60 may apply the nonsinusoidal wave power to the upper electrode 50 to generate an electron beam. The power signal applied to the upper electrode 50 may have a nonsinusoidal voltage waveform. The nonsinusoidal power signal may have a DC pulse portion (S) and a ramp portion (R). The ramp portion (R) may be a portion which is modulated by a compensation current, and may have a waveform which declines gradually over time while decreasing from the maximum to the minimum of the DC pulse portion (S), e.g., a negative slope.

The nonsinusoidal wave power may be applied to the upper electrode 50 to generate an electron beam having constant energy. The electron beam emitted from the upper electrode 50 may be accelerated while progressing across a sheath and may be irradiated onto an upper surface of the wafer W disposed on the lower electrode 34. For example, the sheath may be a layer in a plasma which has a greater density of positive ions. For example, there may be a high density of positive ion of plasma within the sheath.

As the nonsinusoidal wave power is applied to the upper electrode 50, the electron beam B having constant energy may be generated regardless of an insulation material such as polymer deposited on the upper electrode 50 during an etch process, and may be irradiated onto the wafer W to neutralize positive ions (e.g., attached or accumulated on the wafer W), thereby improving vertical etch performance for forming a high aspect ratio hole. For example, the electron beam B may have constant energy even though an insulation layer is deposited on the upper electrode 50 when the nonsinusoidal wave power is applied to the upper electrode 50. The nonsinusoidal wave power applied to the upper electrode 50 may be controlled to generate the electron beam having desired energy, thereby increasing plasma density. For example, the energy of the electron beam B may be adjusted by controlling the nonsinusoidal wave power applied to the upper electrode 50, and a desired density of plasma may be obtained.

In example embodiments, the first power supply 40 may apply selectively or simultaneously a sinusoidal wave power and a nonsinusoidal wave power to the lower electrode 34.

Since the nonsinusoidal wave power is applied to the lower electrode 34, a desired ion energy distribution may be generated on the surface of the wafer W. For example, the nonsinusoidal wave power applied to the lower electrode 34 may be controlled to adjust the ion energy generated on the surface of the wafer W.

Hereinafter, a method of forming a pattern of a semiconductor device using the plasma processing method of FIG. 12 will be explained. For example, this method of forming a pattern of a semiconductor device may be a portion of a method of manufacturing a semiconductor device.

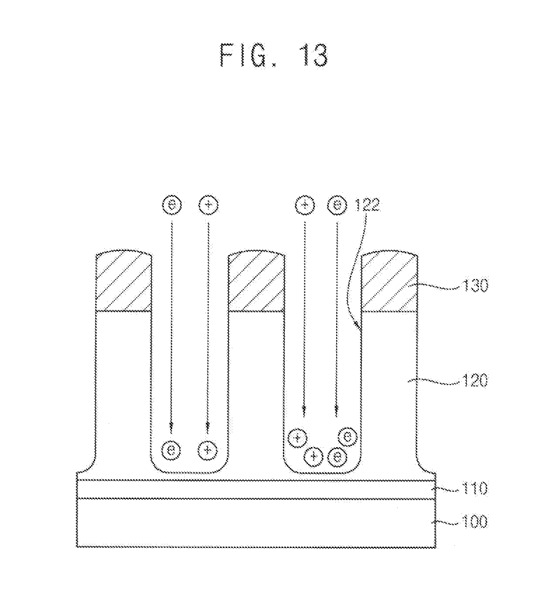

FIG. 13 is a cross-sectional view illustrating a method of forming a pattern of a semiconductor device in accordance with example embodiments.

Referring to FIG. 13, after a photoresist pattern 130 is formed on an object layer 120 to be etched, an etch process may be performed using the photoresist pattern 130 as an etching mask of the object layer 120. For example, the object layer 120 may be an insulation layer or a semiconductor layer formed on the substrate 100.

First, after a substrate 100 having the photoresist pattern 130 formed thereon is loaded into a chamber 20 of a plasma processing apparatus 10 of FIG. 1, a process gas may be supplied onto the substrate 100. The process gas (for example, an etching gas) may be introduced into the chamber 20 through a shower head and then a pressure of the chamber 20 may be controlled to a desired vacuum level by a gas exhaust unit.

Then, a sinusoidal wave power may be applied to a lower electrode 34 to generate plasma within the chamber 20, a nonsinusoidal wave power may be applied to an upper electrode 50, and then, the etch process may be performed on the substrate 100.

The sinusoidal wave power may be applied to the lower electrode 34 to generate plasma within the chamber 20, and the nonsinusoidal wave power may be applied to the upper electrode 50 to generate the electron beam having constant energy. The electron beam emitted from the upper electrode 50 may be accelerated while progressing across a sheath and irradiated onto the substrate 100 disposed on the lower electrode 34.

The electron beam irradiated onto the substrate 100 may neutralize positive ions (e.g., attached or accumulated on the substrate 100) to thereby improve vertical etch performance for forming a high aspect ratio hole 122. The nonsinusoidal wave power applied to the upper electrode 50 may be controlled to generate the electron beam having desired energy, thereby increasing plasma density. For example, the energy of the electron beam may be adjusted by controlling the nonsinusoidal wave power applied to the upper electrode 50, and a desired density of plasma may be obtained.

As mentioned above, the nonsinusoidal wave power may be applied to the upper electrode 50 to form the electron beam having desired energy and to irradiate the substrate with the electron beam. Electrons irradiated onto the substrate may neutralize positive ions (e.g., attached or accumulated on the substrate) to improve straightness of the positive ions and form a high aspect ratio hole.

While FIG. 13 illustrates a method of patterning a layer formed on a substrate 100, in certain embodiments, a similar patterning process may be performed to a bulk semiconductor substrate 100, e.g., a silicon substrate, a germanium substrate or a silicon-germanium substrate. For example, the substrate 100 may be patterned in a method of manufacturing a semiconductor device.

In certain embodiments, a multiple layer formed on the substrate 100 may be patterned by the method described above to manufacture a semiconductor device. The high aspect ratio hole 122 may be a contact via hole. In certain embodiments, a trench may be formed by a similar method to the ones forming the high aspect ratio hole 122.

After forming a high aspect ratio hole or a high aspect ratio trench, the hole or trench may be filled with a conductive material, e.g., copper, gold, tungsten, etc. to form a conductive pattern, e.g., a contact via or a signal line. The substrate 100 may be divided into chips and may be packaged to form a semiconductor device.

A semiconductor device manufactured by a plasma processing apparatus and a plasma processing method in accordance with example embodiments may be used in various systems such as a computing system. The semiconductor device may include finFET, DRAM, VAND, etc. The system may be applied to a computer, a portable computer, a laptop computer, a personal portable terminal, a tablet, a cell phone, a digital music player, etc.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

1. A plasma processing apparatus, comprising;
a chamber including a space configured to process a substrate;
a substrate stage configured to support the substrate within the chamber, the substrate stage including a lower electrode;
an upper electrode disposed in the chamber, the upper electrode facing the lower electrode;
a first power supply including a sinusoidal wave power source configured to apply a sinusoidal wave power to the lower electrode to form plasma within the chamber; and
a second power supply configured to apply a nonsinusoidal wave power to the upper electrode to generate an electron beam.

2. The plasma processing apparatus of claim 1, wherein the upper electrode comprises a first upper electrode arranged to face a middle region of the substrate and a second upper electrode arranged to face a peripheral region of the substrate.

3. The plasma processing apparatus of claim 2, wherein the first upper electrode comprises a first electrode plate having a circular shape and the second upper electrode comprises a second electrode plate having an annular shape surrounding the first electrode plate.

4. The plasma processing apparatus of claim 2, wherein the second power supply is configured to apply a first nonsinusoidal wave power to the first upper electrode and a second nonsinusoidal wave power having a predetermined ratio with respect to the first nonsinusoidal wave power to the second upper electrode.

5. The plasma processing apparatus of claim 2, wherein the plasma processing apparatus is configured to change a ratio of the powers applied to the first and second upper electrodes.

6. The plasma processing apparatus of claim 2, wherein the first upper electrode comprises a plurality of first injection holes which penetrate through the first upper electrode, the plurality of first injection holes configured to supply a gas into the chamber.

7. The plasma processing apparatus of claim 6, wherein the second upper electrode comprises a plurality of second injection holes which penetrate through the second upper electrode, the plurality of second injection holes configured to supply a gas into the chamber.

8. The plasma processing apparatus of claim 1, further comprising a shower head configured to supply a gas into the chamber,
wherein the shower head comprises an electrode support plate which supports the upper electrode, and
wherein the electrode support plate is configured to diffuse the gas such that the gas is injected through injection holes formed in the upper electrode.

9. The plasma processing apparatus of claim 8, wherein the electrode support plate comprises a gas diffusion room therein and gas passages connecting the gas diffusion room to the injection holes.

10. The plasma processing apparatus of claim 8, wherein the upper electrode comprises a first upper electrode arranged to face a middle region of the substrate and a second upper electrode insulated from the first upper electrode and arranged to face a peripheral region of the substrate,
wherein the electrode support plate comprises a first electrode support plate which supports the first upper electrode, and
wherein the first electrode support plate is configured to diffuse the gas such that the gas is injected through first injection holes formed in the first upper electrode.

11. The plasma processing apparatus of claim 10, wherein the first electrode support plate comprises a first gas diffusion room therein and first gas passages connecting the first gas diffusion room to the first injection holes.

12. The plasma processing apparatus of claim 11, wherein the electrode support plate further comprises a second electrode support plate which supports the second upper electrode.

13. The plasma processing apparatus of claim 12, wherein the second electrode support plate comprises a second gas diffusion room therein and second gas passages connecting the second gas diffusion room to second injection holes formed in the second upper electrode.

14. The plasma processing apparatus of claim 1, wherein the first power supply further comprises a nonsinusoidal wave power source configured to apply a nonsinusoidal wave power to the lower electrode.

15. The plasma processing apparatus of claim 14, wherein the first power supply further comprises a switching circuit configured to apply selectively or simultaneously the sinusoidal wave power from the sinusoidal wave power source and the nonsinusoidal wave power from the nonsinusoidal wave power source to the lower electrode.

16. The plasma processing apparatus of claim 15, wherein the switching circuit comprises a first portion disposed between the sinusoidal wave power source and the lower electrode to switch supply of the sinusoidal wave power and a second portion disposed between the nonsinusoidal wave power source and the lower electrode to switch supply of the nonsinusoidal wave power.

17. A plasma processing apparatus, comprising;
a chamber including a space configured to process a substrate;
a substrate stage configured to support the substrate within the chamber, the substrate stage including a lower electrode;
a first upper electrode over the lower electrode, the first upper electrode configured to face a first region of the substrate;
a second upper electrode over the lower electrode, the second upper electrode configured to face a second region of the substrate, the second upper electrode being insulated from the first upper electrode;
a first power supply including a sinusoidal wave power source configured to apply a sinusoidal wave power to the lower electrode to form plasma within the chamber; and
a second power supply configured to apply a nonsinusoidal wave power to each of the first and second upper electrodes.

18. The plasma processing apparatus of claim 17, wherein the first upper electrode is arranged to face a middle region of the substrate and the second upper electrode is arranged to face a peripheral region of the substrate.

19. The plasma processing apparatus of claim 17, wherein the second power supply is configured to apply a first nonsinusoidal wave power to the first upper electrode and a second nonsinusoidal wave power having a predetermined ratio with respect to the first nonsinusoidal wave power to the second upper electrode.

20. The plasma processing apparatus of claim 17, wherein the first and second power supplies are configured to change a ratio of the powers applied to the first and second upper electrodes.

21-37. (canceled)
